(19) United States
(12) Patent Application Publication
(10) Pub. No.: US 2025/0149430 A1
(43) Pub. Date: May 8, 2025

(54) SEMICONDUCTOR PACKAGE

(71) Applicant: SAMSUNG ELECTRONICS CO., LTD., Suwon-si (KR)

(72) Inventor: Seungduk BAEK, Suwon-si (KR)

(73) Assignee: SAMSUNG ELECTRONICS CO., LTD., Suwon-si (KR)

(21) Appl. No.: 18/672,870

(22) Filed: May 23, 2024

(30) Foreign Application Priority Data
Nov. 2, 2023 (KR) 10-2023-0150218

(51) Int. Cl. H01L 23/498; H01L 23/00; H01L 23/48; H01L 23/528; H01L 25/065; H01L 25/18

(52) U.S. Cl. CPC H01L 23/49838; H01L 23/481; H01L 23/5286; H01L 24/08; H01L 25/0657; H01L 24/16; H01L 25/18; H01L 2224/08145; H01L 2224/16225; H01L 2225/06541; H01L 2924/1815

(57) ABSTRACT

Provided is a semiconductor package including a first semiconductor chip including a substrate, interconnects, an insulating layer on the interconnects, first lower pads on the interconnects, and a first passivation layer on the first lower pads, and a second semiconductor chip including second upper pads contacting the first lower pads, a second passivation layer on the second upper pads and contacting the first passivation layer, second lower pads opposite to the second upper pads, and through-electrodes, wherein the first semiconductor chip has a first longer side extending in a first direction and a first shorter side extending in a second direction, the interconnects include intermediate conductors and connection conductors between the intermediate conductors and the first lower pads, a thickness of the connection conductors is greater than that of the intermediate conductors, and a number of the connection conductors is greater than that of the connection conductors.

### CROSS-REFERENCE TO RELATED APPLICATION(S)

This application claims priority to Korean Patent Application No. 10-2023-0150218 filed on Nov. 2, 2023 in the Korean Intellectual Property Office, the disclosure of which is incorporated herein in its entirety by reference.

### BACKGROUND

Embodiments of the present disclosure relate to a semiconductor package.

Semiconductor devices installed in electronic devices require high performance and large capacity as well as miniaturization. To this end, semiconductor packages interconnecting vertically stacked semiconductor chips using through-electrodes (for example, through silicon vias) are being developed.

### SUMMARY

One or more embodiments provide a semiconductor package having improved reliability.

According to an aspect of an embodiment, there is provided a semiconductor package including a first semiconductor chip including a substrate, interconnections on a first surface of the substrate, an insulating layer on at least a portion of the interconnects, first lower pads on the interconnects, and a first passivation layer on at least a portion of each of the first lower pads, and a second semiconductor chip including second upper pads in contact with the first lower pads, a second passivation layer on at least a portion of each of the second upper pads and in contact with the first passivation layer, second lower pads opposite to the second upper pads, and through-electrodes electrically connecting the second upper pads and the second lower pads, wherein in a plan view, the first semiconductor chip has a first longer side extending in a first direction and a first shorter side extending in a second direction, intersecting the first direction, wherein the interconnects include intermediate conductors and connection conductors between the intermediate conductors and the first lower pads, a thickness of each of the connection conductors being greater than a thickness of each of the intermediate conductors, and wherein the connection conductors are disposed in the first direction and the second direction, and a number of the connection conductors in the first direction is greater than a number of the connection conductors in the second direction.

According to another aspect of an embodiment, there is provided a semiconductor package including a first semiconductor chip including interconnects, first lower pads on the interconnects, and a first passivation layer on at least a portion of each of the first lower pads, and a second semiconductor chip including second upper pads in contact with the first lower pads, a second passivation layer on at least a portion of each of the second upper pads and in contact with the first passivation layer, second lower pads opposite to the second upper pads, and through-electrodes electrically connecting the second upper pads and the second lower pads, wherein the interconnects include intermediate conductors and top conductors between the intermediate conductors and the first lower pads, wherein, in a plan view, the first semiconductor chip has a first longer side extending in a first direction and a first shorter side extending in a second direction, intersecting the first direction, and wherein, in the plan view, the top conductors has first sides having a first length in the first direction, and second sides having a second length longer than the first length in the second direction.

According to still another aspect of an embodiment, there is provided a semiconductor package including a first semiconductor chip including interconnects, first lower pads on the interconnects, and a first passivation layer on at least a portion of each of the first lower pads, a second semiconductor chip including second upper pads in contact with the first lower pads, and a second passivation layer on at least a portion of each of the second upper pads and in contact with the first passivation layer, and a mold layer on the second semiconductor chip and adjacent to at least a side surface of the first semiconductor chip, wherein, in a plan view, the first semiconductor chip has a first longer side extending in a first direction and a first shorter side extending in a second direction, intersecting the first direction, wherein, in the plan view, the second semiconductor chip has a second longer side that is longer than the first longer side in the first direction, and a second shorter side that is longer than the first shorter side in the second direction, wherein the interconnects include intermediate conductors and top conductors connecting the intermediate conductors and the first lower pads, and wherein each of the top conductors has a rectangular shape elongated in the second direction.interconnectsinterconnectsinterconnectsinterconnectsinterconnectsinterconnectsinte rconnectsinterconnects

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view of a semiconductor package according to one or more embodiments;

FIG. 2A is a cross-sectional view taken along line I-I′ of FIG. 1, and FIG. 2B is a partially enlarged view of region ‘A’ of FIG. 1;

FIGS. 3A, 3B, 3C, and 3D are plan views illustrating a planar shape of first top conductors according to one or more other embodiments;

FIGS. 4A, 4B, and 4C are diagrams illustrating a manufacturing process of a semiconductor package according to one or more embodiments;

FIG. 5A is a perspective view of a semiconductor package according to one or more embodiments, FIG. 5B is a cross-sectional view taken along line II-II′ of FIG. 5A, FIG. 5C is a partial enlarged view of region ‘B’ of FIG. 5B, and FIG. 5D is a plan view illustrating a planar shape of first top conductors according to one or more embodiments;

FIGS. 6A, 6B, and 6C are diagrams illustrating a manufacturing process of a semiconductor package illustrated in FIG. 5B;

FIG. 7A is a perspective view of a semiconductor package according to one or more embodiments, and FIG. 7B is a plan view illustrating a planar shape of first top conductors of each of a plurality of first semiconductor chips of FIG. 7A;

FIG. 8A is a plan view of a semiconductor package according to one or more embodiments, and FIG. 8B is a cross-sectional view taken along line III-III′ of FIG. 8A;

FIG. 9 is a cross-sectional view of a semiconductor package according to one or more embodiments;

FIGS. 10A, 10B, 10C, and 10D are diagrams illustrating a manufacturing process of the semiconductor package illustrated in FIG. 9; and

FIG. 11A is a cross-sectional view of a semiconductor package according to one or more embodiments, and FIG. 11B is a partial enlarged view of region ‘C’ of FIG. 11A.

### DETAILED DESCRIPTION

Hereinafter, with reference to the accompanying drawings, example embodiments of the present inventive concept will be described as follows. Unless otherwise specified, in this specification, terms such as ‘upper,’ ‘upper surface,’ ‘lower,’ ‘lower surface,’ ‘side’ and the like are based on the drawings, and actually, may vary depending on the direction in which the components are disposed.

Additionally, ordinal numbers such as “first,” “second,” “third,” or the like may be used as labels for specific elements, step portions, directions, or the like to distinguish various elements, step portions, directions, or the like from each other. Terms that are not described using “first,” “second,” or the like in the specification may still be referred to as “first” or “second” in the claims. Additionally, terms referenced by a specific ordinal number (for example, “first” in a particular claim) may be described elsewhere with a different ordinal number (for example, “second” in the specification or another claim).

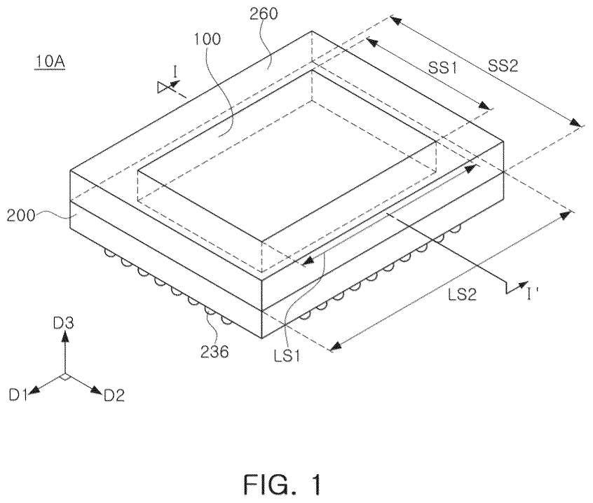

FIG. 1 is a perspective view of a semiconductor package 10A according to one or more embodiments.

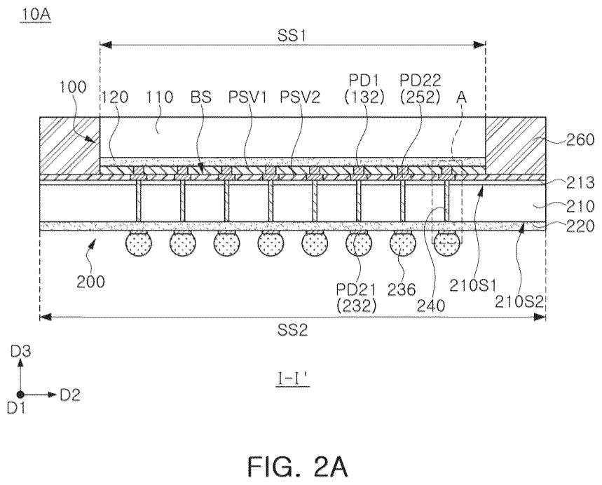

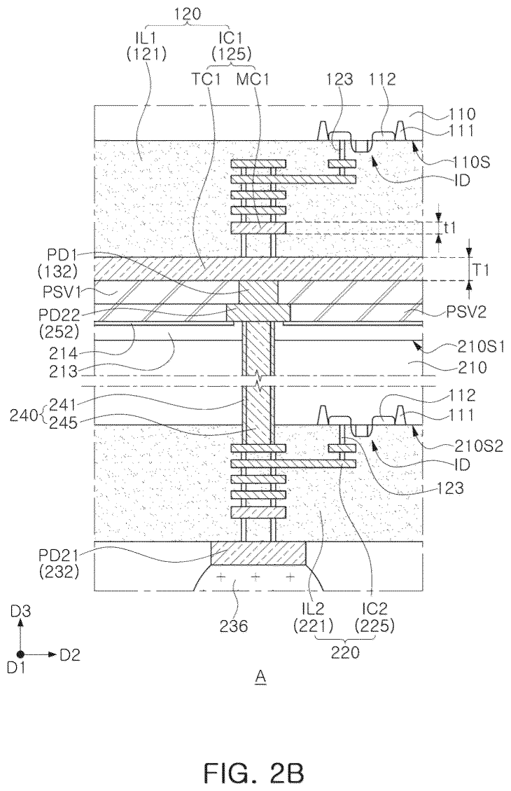

FIG. 2A is a cross-sectional view taken along line I-I′ of FIG. 1, and FIG. 2B is a partial enlarged view of region ‘A’ in FIG. 1.

Referring to FIGS. 1, 2A, and 2B, a semiconductor package 10A according to one or more embodiments may include two or more semiconductor chips facing each other in a vertical direction D3, for example, a first semiconductor chip 100 and a second semiconductor chip 200. Two or more first semiconductor chips 100 may be disposed on the second semiconductor chip 200. The first semiconductor chip 100 and the second semiconductor chip 200 may include chiplets included in a multichip module (MCM). Depending on example embodiments, the semiconductor package 10A may further include a mold layer 260 that seals at least a portion of each of the semiconductor chips 100 and 200. The mold layer 260 may include, for example, epoxy mold compound (EMC), but the material of the mold layer 260 is not particularly limited.

The first semiconductor chip 100 and the second semiconductor chip 200 may be bonded and coupled to each other by inter-metal bonding and inter-dielectric bonding. The semiconductor package 10A may have a bonding surface BS on which a first lower pad PD1 and a first passivation layer PSV1 of the first semiconductor chip 100, and a second upper pad PD22 and a second passivation layer PSV2 of the second semiconductor chip 200, are bonded and combined.

In example embodiments, the first semiconductor chip 100 may be a chip that is picked and placed on the second semiconductor chip 200 that is temporarily supported. Hereinafter, the second semiconductor chip 200 may be referred to as a base chip or a base wafer.

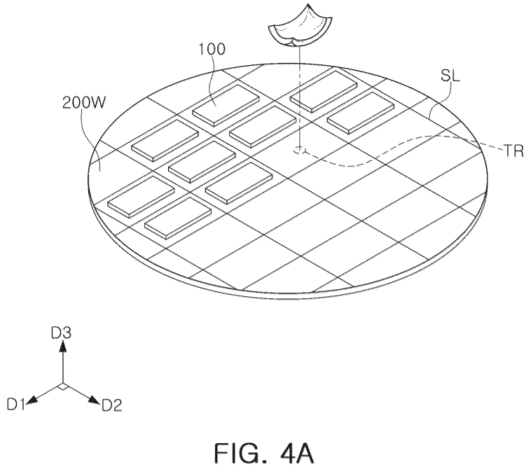

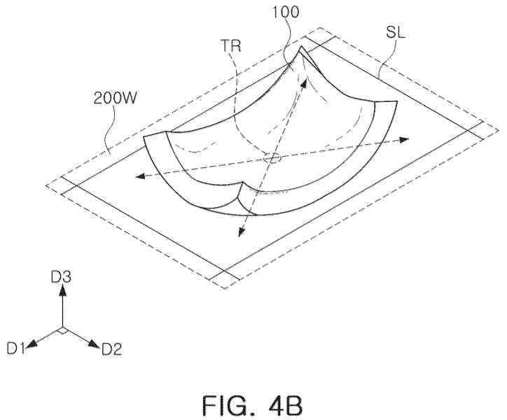

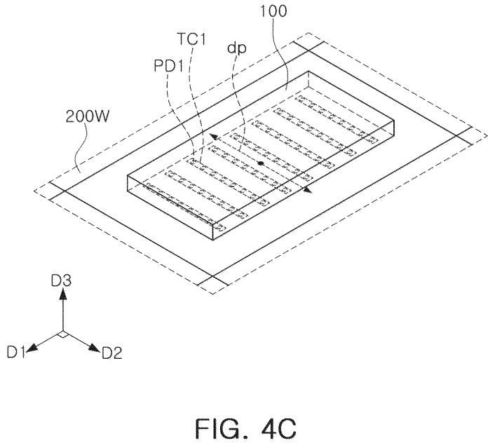

Since first top conductors TC1 of one or more embodiments are spaced apart in a longer side (LS1) direction (D1 direction) of the first semiconductor chip 100, the first semiconductor chip 100 may be more easily bent in the longer side (LS1) direction. In addition, since the first top conductors TC1 of the example embodiment have a short length in a shorter side (SS1) direction (D2 direction) of the first semiconductor chip 100, the first semiconductor chip 100 may also be more easily bent in the shorter side SS1 direction. Accordingly, since the first semiconductor chip 100 is attached to the base chip 200 in a bent state in the longer side (LS1) direction D1 and the shorter side SS1 direction (D2 direction), the attachment region of the first semiconductor chip 100 and the base chip 200 may spread from the center of the first semiconductor chip 100 to the outside. Accordingly, voids generated during the placement of the first semiconductor chip 100 may be reduced, and the discharge path of moisture and voids (discharged in the extending direction of the top conductors TC1) generated during the thermal compression process may be significantly reduced (see FIGS. 4A to 4C). Hereinafter, the longer side (LS1) direction refers to the direction in which the longer side (LS1) extends, and the shorter side SS1 direction (D2 direction) refers to the direction in which the shorter side SS1 extends.

The first semiconductor chip 100 may include a first substrate 110, a first circuit layer 120, a first passivation layer PSV1, and a plurality of first lower pads PD1.

The first substrate 110 may be a semiconductor wafer. The first substrate 110 may include a semiconductor element such as silicon or germanium, or a compound semiconductor such as silicon carbide (SiC), gallium arsenide (GaAs), indium arsenide (InAs), and indium phosphide (InP) for example. The first substrate 110 may include a conductive region 112 and a separation region 111 formed on one surface 110S. The conductive region 112 may be, for example, a well doped with impurities or a structure doped with impurities. The isolation region 111 is a device isolation structure having a shallow trench isolation (STI) structure and may include silicon oxide.

The first circuit layer 120 may be disposed on the first surface 110S of the first substrate 110 in which the conductive region 112 is formed. The first circuit layer 120 may include individual elements ID, a first insulating layer IL1, and a first interconnection IC1. Hereinafter, the first insulating layer IL1 may be referred to as a front insulating layer or an interlayer insulating layer 121. The first interconnection IC1 may be referred to as an interconnect structure 125.

The individual elements ID may be disposed on the first surface 110S of the first substrate 110. The individual elements ID may be electrically connected to the conductive region 112. The individual elements ID may include, for example, FET such as planar FET, FinFET or the like, memory devices such as a flash memory, DRAM, SRAM, EEPROM, PRAM, MRAM, FeRAM, and RRAM, logic elements such as AND, OR, NOT and the like, and various active and/or passive elements such as system LSI, CIS, and MEMS.

The interlayer insulating layer 121 is formed to cover the individual elements ID and the interconnect structure 125, and may electrically separate the individual elements ID disposed on the first substrate 110. The interlayer insulating layer 121 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof. At least a portion of the interlayer insulating layer 121 surrounding the interconnect structure 125 may be composed of a low dielectric layer. The interlayer insulating layer 121 may be formed using a chemical vapor deposition (CVD) process, a flowable CVD process, or a spin coating process.

The interconnect structure 125 may be formed as a multilayered structure including a plurality of interconnection patterns and a plurality of vias formed of, for example, aluminum (Al), gold (Au), cobalt (Co), copper (Cu), nickel (Ni), lead (Pb), tantalum (Ta), tellurium (Te), titanium (Ti), tungsten (W) or combinations thereof. A barrier film (not illustrated) containing titanium (Ti), titanium nitride (TiN), tantalum (Ta), or tantalum nitride (TaN) may be disposed between the interconnection pattern or/and via and the interlayer insulating layer 121. The interconnect structure 125 may be electrically connected to the individual elements ID by an interconnector 123 (for example, a contact plug). The interconnect structure 125 may include a signal interconnection, a power interconnection, and a ground interconnection.

The first interconnection IC1 may include first intermediate conductors MC1 and first top conductors TC1. Hereinafter, the first top conductors TC1 may be referred to as connection conductors. The first intermediate conductors MC1 may be disposed in the first insulating layer IL1. The first intermediate conductors MC1 may be located between the first surface 110S of the first substrate 110 and the first top conductors TC1. The first top conductors TC1 may be positioned between the first intermediate conductors MC1 and the plurality of first pads PD1 in the vertical direction D3. A thickness T1 of the first top conductors TC1 may be greater than a thickness t1 of the first intermediate conductors MC1. The thickness T1 of the first top conductors TC1 may be greater than or equal to about 1 μm, for example, may range from about 1 μm to about 30 μm, from about 1 μm to about 20 μm, from about 1 μm to about 10 μm, from about 1 μm to about 5 μm, or the like, but embodiments are not limited thereto. The first top conductors TC1 may include aluminum (Al) or an alloy thereof, but embodiments are not limited thereto. Depending on example embodiments, the first top conductors TC1 may include a material similar to the first intermediate conductors MC1, for example, copper (Cu) or an alloy thereof.

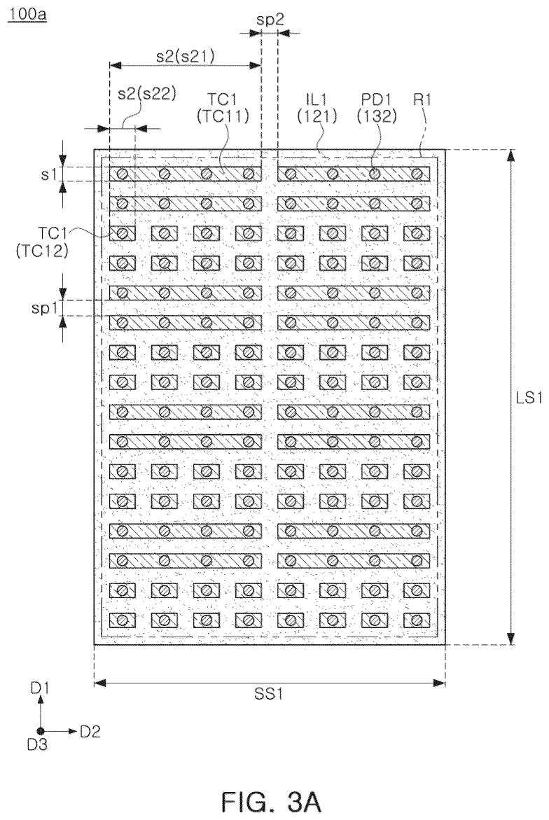

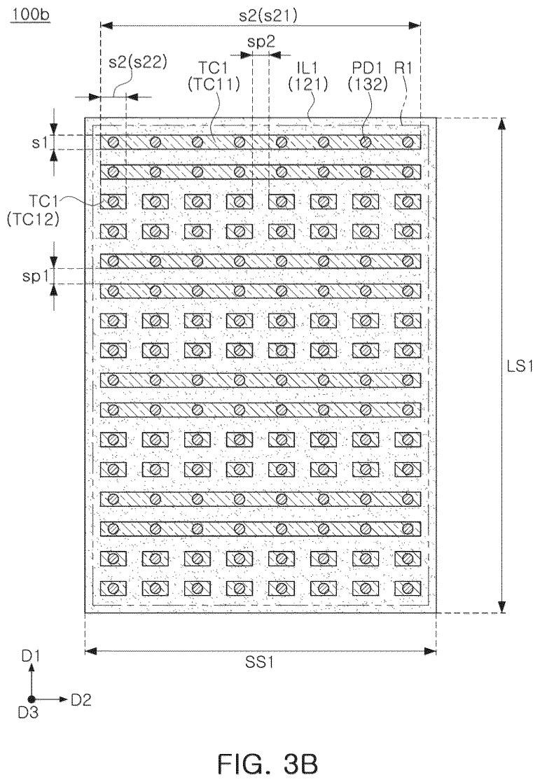

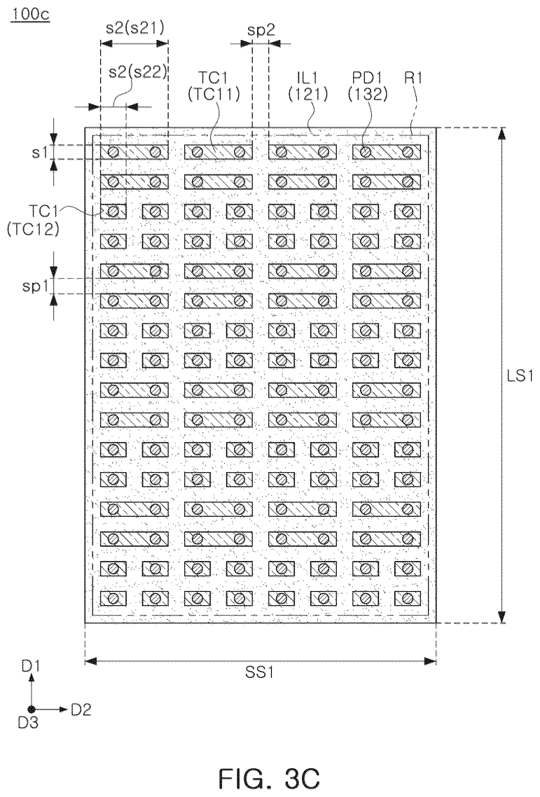

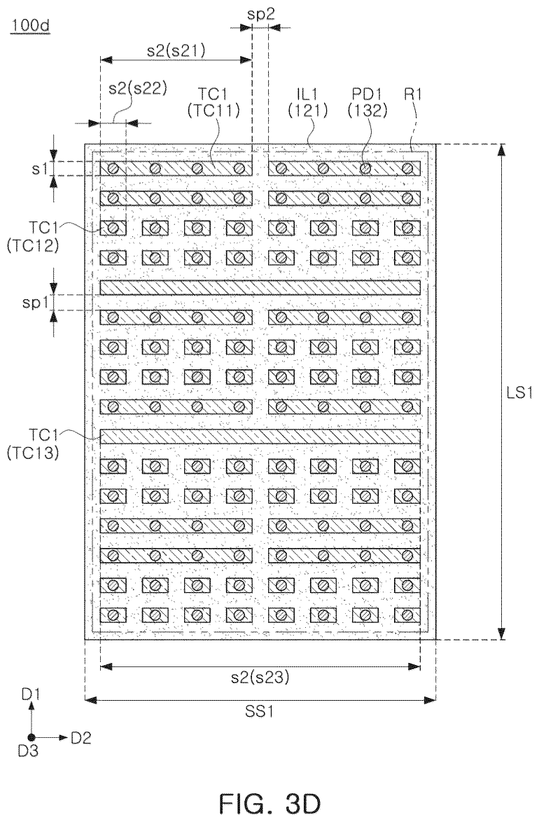

In one or more embodiments, the first top conductors TC1 may extend lengthwise in the shorter side (SS1) direction (D2 direction) of the first semiconductor chip 100. For example, on a plane, the first semiconductor chip 100 may include a first longer side LS1 extending in the first direction D1 and a first shorter side SS1 extending in a second direction D2 intersecting the first direction D1, and the first top conductors TC1 may have a rectangular shape long in the second direction D2. The planar shape of the first top conductors TC1 will be described in more detail with reference to FIGS. 3A to 3D.

The plurality of first lower pads PD1 may be disposed on the first interconnection IC1. The plurality of first lower pads PD1 may be electrically connected to the first interconnection IC1 through the first top conductor TC1. The plurality of first lower pads PD1 may include at least one of copper (Cu), nickel (Ni), gold (Au), silver (Ag), titanium (Ti), titanium nitride (TiN), tantalum (Ta), and tantalum nitride (TaN). For example, the plurality of first lower pads PD1 may include at least one of copper (Cu) or an alloy thereof. To distinguish the positions of components within the first semiconductor chip 100, the plurality of first lower pads PD1 may be referred to as front pads 132. At least some of the plurality of first lower pads PD1 may be in direct contact with the second upper pads PD22 of the second semiconductor chip 200.

A plurality of second upper pads PD22 may be disposed on through-electrodes 240. The plurality of second upper pads PD22 may be electrically connected to the second interconnection IC2 through the through-electrodes 240. The plurality of second upper pads PD22 may include at least one of copper (Cu), nickel (Ni), gold (Au), silver (Ag), titanium (Ti), titanium nitride (TiN), tantalum (Ta), and tantalum nitride (TaN). For example, the plurality of second upper pads PD22 may include at least one of copper (Cu) or an alloy thereof. To distinguish the positions of components within the second semiconductor chip 200, the plurality of second upper pads PD22 may be referred to as back pads 252. The back pads 252 may be electrically connected to the second interconnection IC2 and/or the second front pad 232 through the through-electrodes 240.

The first passivation layer PSV1 may be formed to surround the side surfaces of the plurality of first lower pads PD1. The first passivation layer PSV1 may form the bonding surface BS provided for inter-dielectric bonding between the plurality of first lower pads PD1. The first passivation layer PSV1 may include, for example, silicon oxide (SiO) and/or silicon carbonitride (SiCN). The first passivation layer PSV1 may be in direct contact with the second passivation layer PSV2 of the second semiconductor chip 200.

The second passivation layer PSV2 may be formed to surround the side surfaces of the plurality of second upper pads PD2. The second passivation layer PSV2 may form the bonding surface BS provided for inter-dielectric bonding between the plurality of second upper pads PD2. The second passivation layer PSV2 may include, for example, silicon oxide (SiO) and/or silicon carbonitride (SiCN).

The second semiconductor chip 200 may be disposed on a first surface of the first semiconductor chip 100. The second semiconductor chip 200 may be disposed in a direction in which the plurality of second upper pads PD22 face the front pads 132 of the first semiconductor chip 100.

The second semiconductor chip 200 may have a rectangular shape with a longer side in the first direction D1 or the second direction D2. For example, the second semiconductor chip 200 may have a longer side LS2 extending in the first direction D1 or the second direction D2. The length of the second longer side LS2 of the second semiconductor chip 200 may be greater than the length of the first longer side LS1 of the first semiconductor chip 100. For example, the second semiconductor chip 200 may include a second longer side LS2 that is longer than the first longer side LS1 of the first semiconductor chip 100 in the first direction D1, and a second shorter side SS2 that is longer than the first shorter side SS1 of the first semiconductor chip 100 in the second direction D2. For example, the second longer side LS2 of the second semiconductor chip 200 extends in the second direction D2, and the second shorter side SS2 may extend in the first direction D1. However, embodiments are not limited thereto, and for example, the second semiconductor chip 200 may have a square shape.

The second semiconductor chip 200 may include a second substrate 210, a second circuit layer 220, a second passivation layer PSV2, a plurality of second upper pads PD22, a plurality of through-vias 240, and a plurality of second lower pads PD21. The second semiconductor chip 200 may include components substantially similar to the components of the first semiconductor chip 100, and for example, may include a second substrate 210, a second circuit layer 220, a second passivation layer PSV2, and a plurality of second lower pads PD21. Accordingly, identical or similar components are referred to by identical or similar terms and/or reference numerals, and redundant descriptions are omitted below. A second insulating layer IL2 may be referred to as a front insulating layer or an interlayer insulating layer 221, and the second interconnection IC2 may be referred to as an interconnect structure 225.

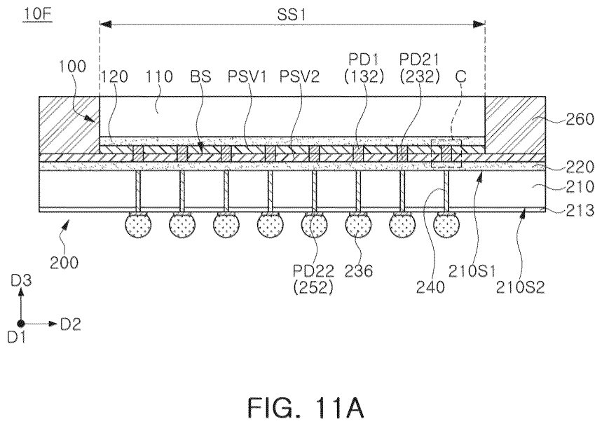

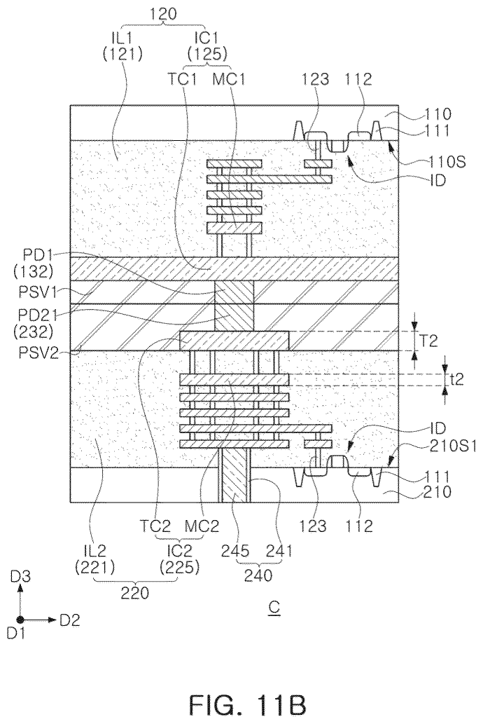

The through-electrodes 240 may penetrate through a first surface 210S1 and a second surface 210S2 of the second substrate 210 to electrically connect the second interconnection IC2 and the plurality of second upper pads PD22. The first surface 210S1 of the second substrate 210 may be referred to as the front or back surface depending on whether the active region 112 is formed. For example, the first surface 210S1 of the second substrate 210 in this embodiment may be referred to as the back surface, and the first surface 210S1 of the second substrate 210 in the example embodiment of FIG. 11B may be referred to as the front surface. The through-electrodes 240 may include a via plug 245 and a side barrier layer 241 surrounding the side thereof. The via plug 245 may include, for example, tungsten (W), titanium (Ti), aluminum (Al), or copper (Cu), and may be formed by a plating process, PVD process, or CVD process. The side barrier layer 241 may include titanium (Ti), titanium nitride (TiN), tantalum (Ta), or tantalum nitride (TaN), and may be formed by a plating process, PVD process, or CVD process. A side insulating film containing an insulating material (for example, high aspect ratio process (HARP) oxide), such as silicon oxide, silicon nitride, or silicon oxynitride may be formed between the side barrier layer 241 and the second substrate 210.

The through-electrodes 240 may penetrate an insulating protective layer 213 formed on the first surface 210S1 of the second substrate 210. The insulating protective layer 213 may include, for example, silicon oxide (SiO), silicon nitride (SiN), silicon carbide (SiC), silicon oxynitride (SiON), or silicon carbonitride (SiCN). A buffer film 214, such as a polishing-stop layer or barrier, may be disposed on the insulating protective layer 213. For example, the buffer film may include silicon nitride, silicon carbide, silicon oxynitride, or silicon carbonitride.

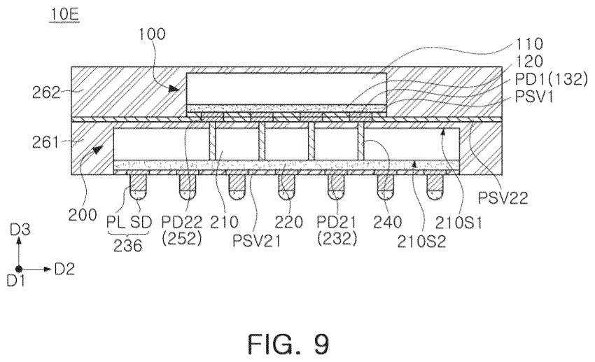

The plurality of second lower pads PD21 may be disposed on the second surface 210S2 of the second substrate 210. The plurality of second lower pads PD21 may be referred to as front pads 232. The plurality of second lower pads PD21 may be connected to connection bumps 236. The connection bumps 236 may include, for example, tin (Sn), indium (In), bismuth (Bi), antimony (Sb), copper (Cu), silver (Ag), zinc (Zn), lead (Pb), and/or alloys thereof. Depending on example embodiments, the connection bumps 236 may have a combined form of a metal pillar and a solder ball (see FIG. 9).

Hereinafter, the planar shape of the first top conductors TC1 will be described with reference to FIGS. 3A to 3D.

FIGS. 3A to 3D are plan views illustrating the planar shape of the first top conductors TC1 according to an example modification.

Referring to FIG. 3A, a first semiconductor chip 100a of one or more other embodiments may have a first longer side LS1 extending in the first direction D1 and a first shorter side SS1 extending in the second direction D2. The first top conductors TC1 may be disposed in a circuit region R1 of the first semiconductor chip 100a. The first top conductors TC1 may be formed to facilitate bending of the first semiconductor chip 100a in the first longer side (LS1) and first shorter side (SS1) directions.

In a plan view, the first top conductors (which may be referred to as connection conductors) TC1 may have first sides s1 extending in the first direction D1 and second sides s2 extending in the second direction D2. The length of the first sides s1 may be shorter than the length of the second sides s2. The length of the first sides s1 may correspond to the line width of the first top conductors TC1. For example, the length of the first sides s1 may range from about 1 μm to about 50 μm, from about 1 μm to about 40 μm, from about 1 μm to about 30 μm, from about 1 μm to about 20 μm, or from about 5 μm to about 10 μm, but is not limited thereto.

The distribution of the first sides s1 with respect to the first longer side LS1 may be smaller than the distribution of the second sides s2 with respect to the first shorter side SS1. On a plane, a first ratio (s1/LS1) of the sum of lengths of the first sides (s1) adjacent to the first longer side (LS1) of the first semiconductor chip 100a and the length of the first longer side (LS1) may be smaller than a second ratio (s2/SS1) of the sum of lengths of the second sides (s2) adjacent to the first shorter side (SS1) and the length of the first shorter side (SS1).

The number of first top conductors TC1 arranged in the first direction D1 may be greater than the number of first top conductors TC1 arranged in the second direction D2. For example, as illustrated in FIG. 3A, the number of first top conductors TC1 arranged in the first direction D1 is 16, and the number of first top conductors TC1 arranged in the second direction D2 may be 2 or 8. In addition, the number of first spaces sp1 between the first top conductors TC1 arranged in the first direction D1 may be greater than the number of second spaces sp2 between the first top conductors TC1 arranged in the second direction D2. For example, as illustrated in FIG. 3A, the number of first spaces sp1 arranged in the first direction D1 is 15, and the number of second spaces sp2 arranged in the second direction D2 may be 1 or 7. The first spaces sp1 may extend in the second direction D2 and may be regions that do not overlap the first top conductors TC1. The width of the first spaces sp1 in the first direction D1 may be less than or equal to about 50 μm, and for example, may range from about 1 μm to about 50 μm, from about 1 μm to about 40 μm, from about 1 μm to about 30 μm, from about 1 μm to about 20 μm, or from about 5 μm to about 10 μm, but embodiments are not limited thereto.

The first sides s1 of the first top conductors TC1 may have the same length. Depending on example embodiments, the second sides s2 of the first top conductors TC1 may include conductors of different lengths. For example, the first top conductors TC1 may include a first group of top conductors TC11 and a second group of top conductors TC12 having second sides s2 of different lengths. The length of the second sides s21 of the first group of top conductors TC11 may be greater than the length of the second sides s22 of the second group of top conductors TC12. The first group of top conductors TC11 may be connected to a greater number of first lower pads PD1 than the second group of top conductors TC12. For example, the top conductors TC11 of the first group may be connected to two or more first lower pads PD1 arranged in the second direction D2, and the connection conductors TC2 of the second group may be connected to the first lower pads PD1 at 1:1. Depending on example embodiments, the top conductors TC11 of the first group are connected to at least one of a power interconnection and a ground interconnection, and the top conductors TC12 of the second group may be connected to signal interconnection, but embodiments are not limited thereto.

Referring to FIG. 3B, a first semiconductor chip 100b of an example modification may include a first group of top conductors TC11 that are not segmented in the second direction D2. The length of the second sides s21 of the top conductors TC11 of the first group may exceed ½ of the length of the first shorter side SS1 of the first semiconductor chip 100b. The length of the second sides s21 of the first group of top conductors TC11 may be greater than the length of the second sides s22 of the second group of top conductors TC12. The first group of top conductors TC11 may be connected to a greater number of first lower pads PD1 than the second group of top conductors TC12. For example, the top conductors TC11 of the first group may be connected to at least one of a power interconnection and a ground interconnection, but embodiments are not limited thereto.

Referring to FIG. 3C, a first semiconductor chip 100c of an example modification may include a first group of top conductors TC11 that are segmented two or more times in the second direction D2. The length of the second sides s21 of the top conductors TC11 of the first group may be less than half the length of the first shorter side SS1 of the first semiconductor chip 100c. The length of the second sides s21 of the first group of top conductors TC11 may be greater than the length of the second sides s22 of the second group of top conductors TC12. The first group of top conductors TC11 may be connected to a greater number of first lower pads PD1 than the second group of top conductors TC12. For example, the top conductors TC11 of the first group may be connected to at least one of a power interconnection and a ground interconnection, but embodiments are not limited thereto.

Referring to FIG. 3D, a first semiconductor chip 100d of one or more other example embodiments may further include a third group of top conductors TC13. The third group of top conductors TC13 may not be electrically connected to the first lower pads PD1. The length of the second sides s23 of the third group of top conductors TC13 may exceed ½ of the length of the first shorter side SS1 of the first semiconductor chip 100d. For example, non-functional pads may be disposed on the third group of top conductors TC13. For example, the third group of top conductors TC13 may be connected to at least one of a power interconnection and a ground interconnection, but embodiments are not limited thereto.

FIGS. 4A to 4C are diagrams illustrating the manufacturing process of a semiconductor package according to one or more embodiments.

Referring to FIG. 4A, first semiconductor chips 100 are pre-bonded on a base wafer 200 W. The base wafer 200 W may include a plurality of base chips (for example, the second semiconductor chip 200 in FIG. 1) divided by scribe lanes SL. In one or more embodiments, the pick-and-place device applies stress to the first semiconductor chips 100, such that the first semiconductor chips 100 may be placed on the base wafer 200 W in a bent state in the longer and shorter side directions. Accordingly, the area of an attachment region TR of the first semiconductor chip 100 and the base wafer 200 W may be significantly reduced. In this case, pre-bonding refers to a process of simply placing the first semiconductor chip 100 on the base wafer 200 W without applying pressure or heat.

Referring to FIG. 4B, the first semiconductor chip 100 is attached on the base wafer 200 W in a bent state in the longer side direction D1 and the shorter side direction D2, and the attachment region TR of the first semiconductor chip 100 and the base chip 200 may spread outward from the center of the first semiconductor chip 100. Accordingly, voids generated at the interface between the first semiconductor chip 100 and the base wafer 200 W may be reduced.

Referring to FIG. 4C, a thermal compression process may be performed to bond the first semiconductor chip 100 and the base wafer 200 W. The thermal compression process may be performed in a thermal atmosphere ranging from about 100° C. to about 300° C. However, the temperature of the thermal atmosphere is not limited to the above-mentioned range and may vary. The top conductors TC1 of the first semiconductor chip 100 adjacent to the base wafer 200 W may form a discharge path dp extending in the shorter side direction D2 of the first semiconductor chip 100. Therefore, moisture and voids generated during the thermal compression process may be more easily removed, and the quality of the bonding surface may be improved.

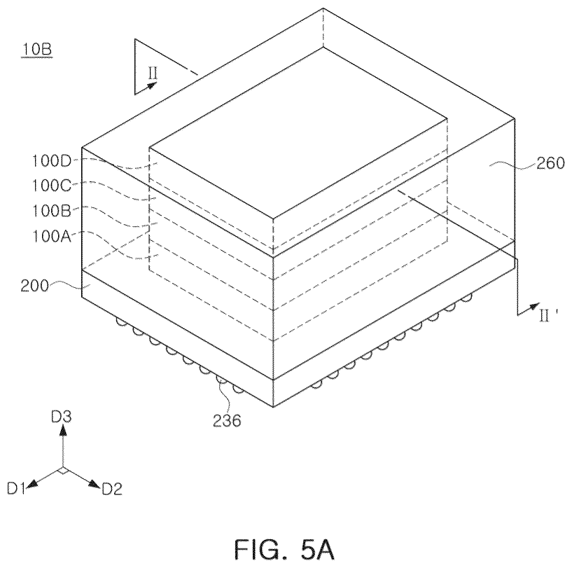

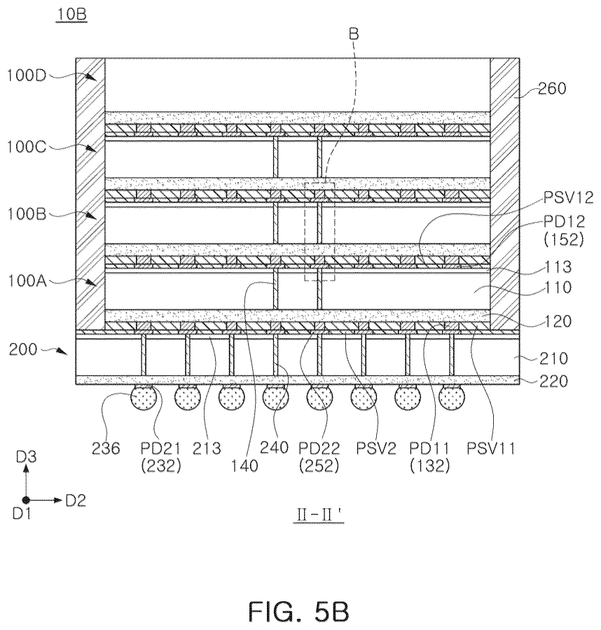

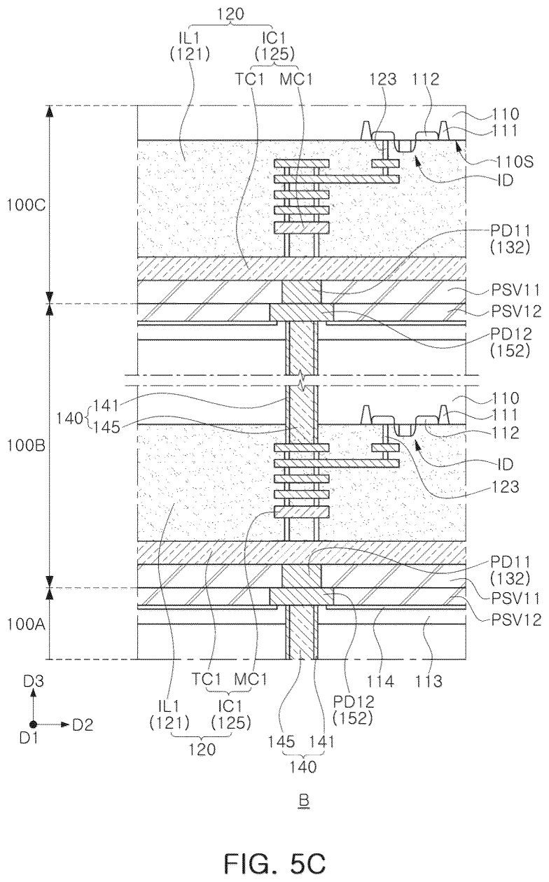

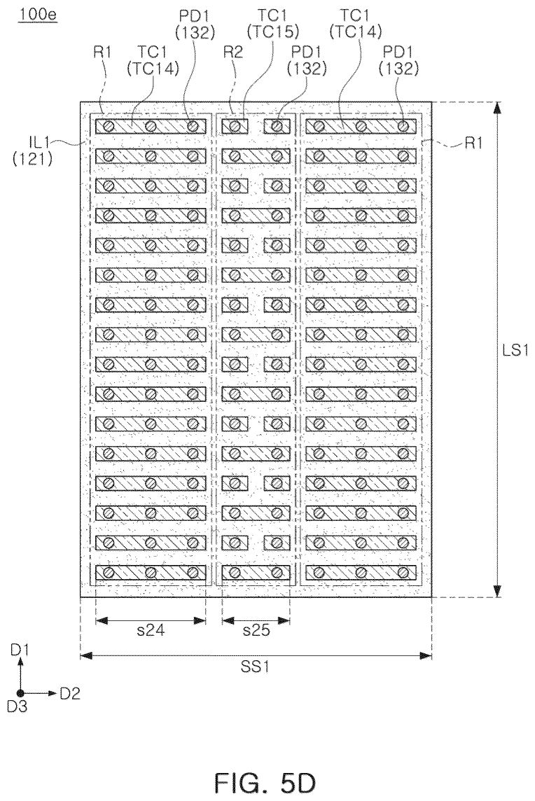

FIG. 5A is a perspective view of a semiconductor package 10B according to one or more embodiments, FIG. 5B is a cross-sectional view taken along line II-II′ of FIG. 5A, FIG. 5C is a partial enlarged view of region ‘B’ in FIG. 5B, and FIG. 5D is a plan view illustrating the planar shape of the first top conductors TC1 according to one or more other example embodiments.

Referring to FIGS. 5A, 5B, and 5C, the semiconductor package 10B of one or more embodiments may have the same or similar features as those described with reference to FIGS. 1 to 4C, except that it includes a plurality of first semiconductor chips 100A, 100B, 100C and 100D stacked in the vertical direction D3 on the second semiconductor chip 200.

The plurality of first semiconductor chips 100A, 100B, 100C and 100D may include a top first semiconductor chip 100D, and first semiconductor chips 100A, 100B and 100C between the top first semiconductor chip 100D and the second semiconductor chip 200. The plurality of first semiconductor chips 100A, 100B, 100C, and 100D may include the same or similar components as the first semiconductor chip 100 described in FIGS. 2A and 2B. However, some of the first semiconductor chips 100A, 100B and 100C excluding the top first semiconductor chip 100D may further include a first through-electrode 140, first upper pads PD12, and a first upper passivation layer PSV12. The upper surface of the top first semiconductor chip 100D may not be covered by a mold layer 260, but may be covered by the mold layer 260.

The first through-electrodes 140 may penetrate through the first surface 110S1 and the second surface 110S2 of the first substrate 110 to electrically connect the first interconnection IC1 and the first upper pads PD12. The first through-electrodes 140 may include a via plug 145 and a side barrier layer 141 surrounding the side of the via plug 145. The via plug 145 may include, for example, tungsten (W), titanium (Ti), aluminum (Al), or copper (Cu), and may be formed by a plating process, PVD process, or CVD process. The side barrier layer 141 may include titanium (Ti), titanium nitride (TiN), tantalum (Ta), or tantalum nitride (TaN), and may be formed by a plating process, PVD process, or CVD process. A side insulating film (not illustrated) containing an insulating material (for example, HARP oxide) such as silicon oxide, silicon nitride, or silicon oxynitride may be formed between the side barrier layer 141 and the first substrate 110. The first through-electrodes 140 may penetrate an insulating protective layer 113. The insulating protective layer 113 may include, for example, silicon oxide (SiO), silicon nitride (SiN), silicon carbide (SiC), silicon oxynitride (SiON), or silicon carbonitride (SiCN). A buffer film 114, such as a polishing-stop layer or barrier, may be disposed on the insulating protective layer 113.

The first upper pads PD12 may be disposed on the first through-electrodes 140. The first upper pads PD12 may be electrically connected to the first interconnection IC1 through the first through-electrodes 140. The first upper pads PD12 may include at least one of copper (Cu), nickel (Ni), gold (Au), silver (Ag), titanium (Ti), titanium nitride (TiN), tantalum (Ta), and tantalum nitride (TaN). For example, the first upper pads PD12 may include at least one of copper (Cu) or an alloy thereof. To distinguish the positions of components within the first semiconductor chip 100, the first top pads PD12 may be referred to as back pads 152. The first upper pads PD12 may be in contact with the first lower pads PD11 adjacent thereto in the vertical direction D3.

The first upper passivation layer PSV12 may be formed to surround the side surfaces of the second upper pads PD12. The first upper passivation layer PSV12 may form a bonding surface provided for inter-dielectric bonding between the second upper pads PD12. The first upper passivation layer PSV12 may include, for example, silicon oxide (SiO) and/or silicon carbonitride (SiCN). The first upper passivation layer PSV12 may be in contact with the first lower passivation layer PSV11 adjacent thereto in the vertical direction D3.

For example, the second semiconductor chip 200 may be a buffer chip or a control chip including a plurality of logic elements and/or memory elements. The second semiconductor chip 200 may transmit signals from the first semiconductor chips 100A, 100B, 100C and 100D stacked on the second semiconductor chip 200 to the outside, and may also transmit signals and power from the outside to the first semiconductor chips 100A, 100B, 100C and 100D. The first semiconductor chips 100A, 100B, 100C, and 100D may be memory chips including volatile memory devices such as DRAM and SRAM, or non-volatile memory devices such as PRAM, MRAM, FeRAM, or RRAM.

Referring to FIG. 5D together, a first semiconductor chip 100e of one or more other example embodiments may include at least one first circuit region R1 extending in the longer side direction D1, and a second circuit region R2 adjacent to at least one side of the at least one first circuit region R1 in the shorter side direction D2. The first top conductors TC1 may include a fourth group of top conductors TC14 disposed in the first circuit region R1, and a fifth group of top conductors TC15 disposed in the second circuit region R2. The width of the first circuit region R1 in the second direction D2 may be greater than the width of the second circuit region R2 in the second direction D2. The length of the second sides s24 of the fourth group of top conductors TC14 in the second direction D2 may be greater than the length of the second sides s25 of the fifth group of top conductors TC15 in the second direction D2. The first circuit region R1 may include a memory circuit (or memory block) including memory cells. For example, the first circuit region R1 may include a plurality of memory cells, a plurality of word lines, and a plurality of bit lines. The second circuit region R2 may include an input/output circuit for the memory circuit.

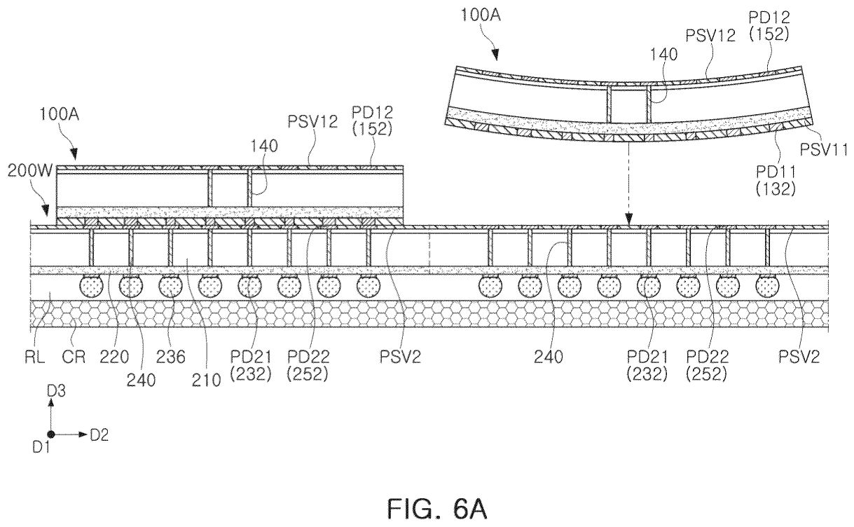

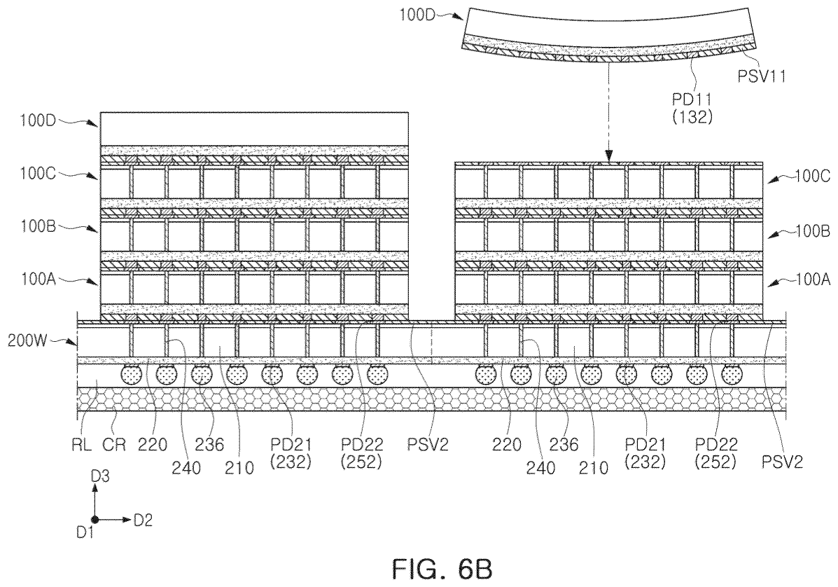

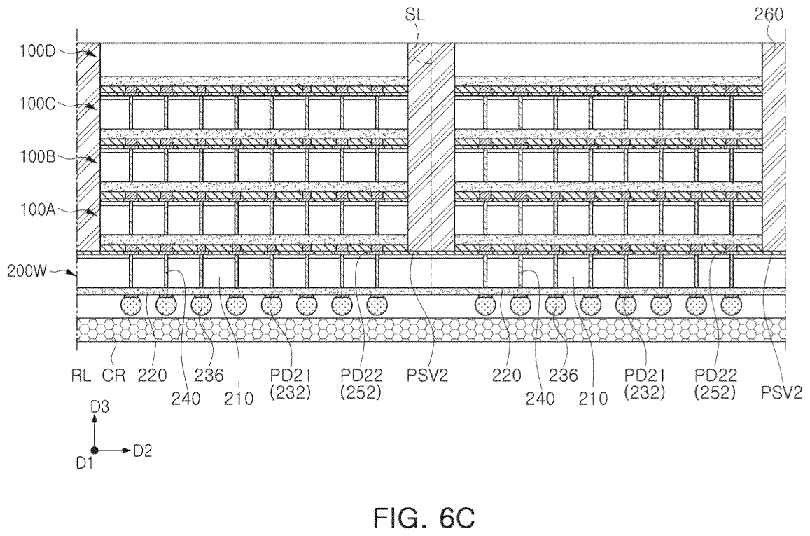

FIGS. 6A to 6C are diagrams illustrating the manufacturing process of the semiconductor package 10B illustrated in FIG. 5B.

Referring to FIG. 6A, the first semiconductor chip 100A may be placed on the base wafer 200 W.

The base wafer 200 W may be temporarily supported on a carrier wafer CR by a bonding material layer RL such as glue. The base wafer 200 W may include components for a plurality of base chips. For example, the base wafer 200 W may include a second substrate 210, a second circuit layer 220, second lower pads PD21, second upper pads PD22, a second passivation layer PSV2, a through-electrode 240, and the like. Additionally, connection bumps 236 buried in the bonding material layer RL may be disposed on the lower portion of the base wafer 200 W.

The first semiconductor chip 100A may be disposed such that the first lower pads PD11 and the first passivation layer PSV11 are in contact with the upper surface of the base wafer 200 W. Afterwards, a thermal compression process may be performed to bond the first passivation layer PSV11 and the second passivation layer PSV2, and the first lower pads PD11 and the second upper pads PD22. Since the first semiconductor chip 100A is attached to the base wafer 200 W in a bent state in the longer side direction D1 and the shorter side direction D2, voids generated at the interface between the first semiconductor chip 100 and the base wafer 200 W may be reduced. Additionally, in the subsequent thermal compression process, moisture and voids may be more easily discharged in the shorter side direction D2 of the first semiconductor chip 100.

Referring to FIG. 6B, Additional first semiconductor chips 100B, 100C, and 100D may be stacked on the first semiconductor chip 100A. The additional first semiconductor chips 100B, 100C, and 100D may be stacked by repeatedly performing the process of FIG. 6A. Since pre-bonding and thermocompression bonding of the plurality of first semiconductor chips 100A, 100B, 100C, and 100D are performed in the manner described with reference to FIGS. 4A to 4C, respectively, a bonding interface of excellent quality may be formed.

Referring to FIG. 6C, a mold layer 260 is formed to cover a plurality of first semiconductor chips 100A, 100B, 100C, and 100D, and by cutting along the scribe lane SL, semiconductor packages may be separated.

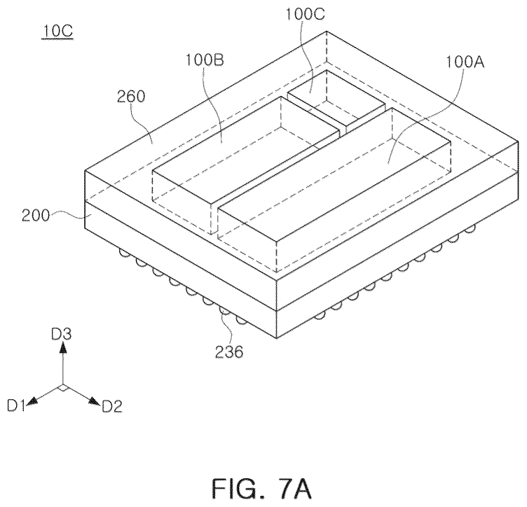

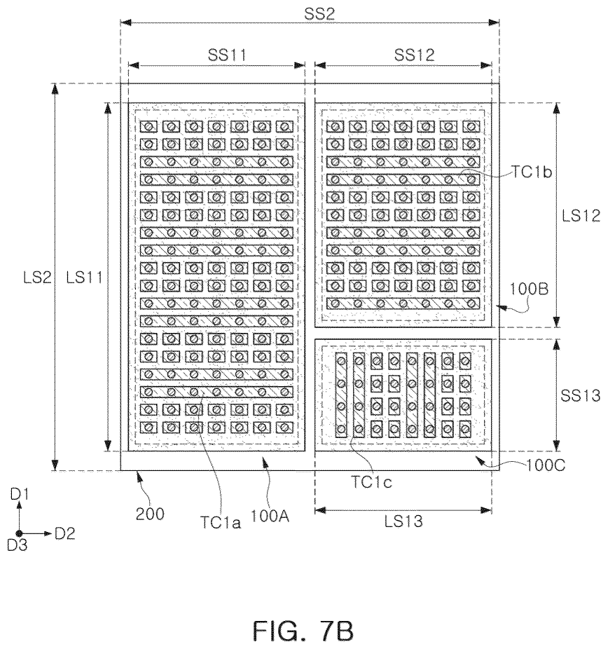

FIG. 7A is a perspective view of a semiconductor package 10C according to one or more embodiments, and FIG. 7B is a plan view illustrating the planar shape of first top conductors TC1a, TC1b, and TC1c of a plurality of first semiconductor chips 100A, 100B, and 100C of FIG. 7A, respectively.

Referring to FIGS. 7A and 7B, the semiconductor package 10C of one or more embodiments may have the same or similar features as those described with reference to FIGS. 1 to 5D, except that it includes a plurality of first semiconductor chips 100A, 100B, and 100C disposed in the horizontal direction (D1 and D2) on a second semiconductor chip 200.

The plurality of first semiconductor chips 100A, 100B, and 100C and the second semiconductor chip 200 may be chiplets included in a multichip module (MCM). The plurality of first semiconductor chips 100A, 100B, and 100C may include a first chiplet 100A, a second chiplet 100B, and a third chiplet 100C. For example, the first chiplet 100A may be a central processor (CPU), the second chiplet 100B may be a graphics processor (GPU), the third chiplet 100C may be a field programmable gate array (FPGA) chip, and the second semiconductor chip 200 may include an I/O chip or an active interposer. For example, the second semiconductor chip 200 may include I/O elements, DC/DC converters, sensors, test circuits, and the like therein.

As illustrated in FIG. 7B, the first chiplet 100A, the second chiplet 100B, and the third chiplet 100C may be bonded on the second semiconductor chip 200. The second semiconductor chip 200 may have a second longer side LS2 extending in the first direction and a second shorter side SS2 extending in the second direction D2.

The first chiplet 100A may have a 1-1 longer side LS11 extending in the first direction D1 and a 1-1 shorter side SS11 extending in the second direction D2. The first chiplet 100A may be disposed such that the 1-1 longer side LS11 corresponds to the second longer side LS2, and the 1-1 shorter side SS11 corresponds to the second shorter side SS2. The 1-1 top conductors TC1a of the first chiplet 100A may be formed in a rectangular shape extending in the direction of the 1-1 shorter side SS11.

The second chiplet 100B may have a 1-2 longer side LS12 extending in the first direction D1 and a 1-2 shorter side SS12 extending in the second direction D2. The second chiplet 100B may be disposed such that the 1-2 longer side LS12 corresponds to the second longer side LS2, and the 1-2 shorter side SS12 corresponds to the second shorter side SS2. The 1-2 top conductors TC1b of the second chiplet 100B may be formed in a rectangular shape extending in the direction of the 1-2 shorter side SS12.

The third chiplet 100C may have a 1-3 longer side LS13 extending in the second direction D2 and a 1-3 shorter side SS13 extending in the first direction D1. The third chiplet 100C may be disposed such that the 1-3 longer side LS13 corresponds to the second shorter side SS2, and the 1-3 shorter side SS13 corresponds to the second longer side LS2. The 1-3 top conductors TC1c of the third chiplet 100C may be formed in a rectangular shape extending in the 1-3 longer side LS13 direction. For example, For example, the 1-3 top conductors TC1c may be formed in a direction that intersects the 1-1 top conductors TC1a and the 1-2 top conductors TC1b.

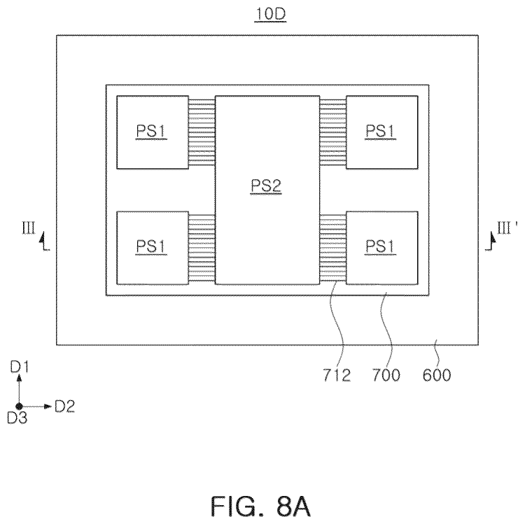

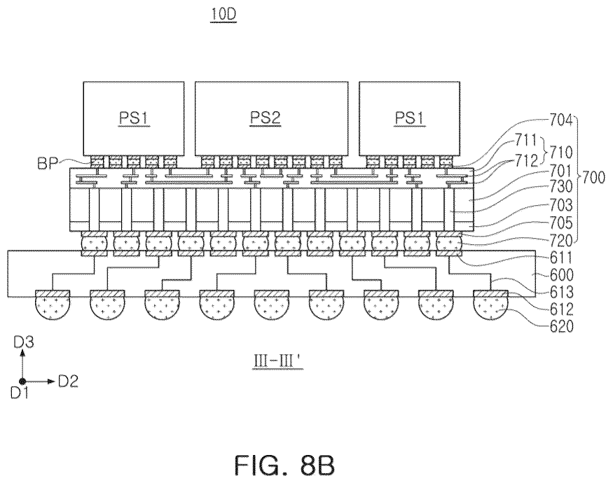

FIG. 8A is a plan view of a semiconductor package 10D according to one or more embodiments, and FIG. 8B is a cross-sectional view taken along line III-III′ in FIG. 8A.

Referring to FIGS. 8A and 8B, the semiconductor package 10D of one or more embodiments may include a package substrate 600, an interposer substrate 700, and at least one package structure (PS1, PS2). At least one package structure (PS1, PS2) may be provided in more or less numbers than illustrated in the drawings.

At least one package structure (PS1, PS2) may include a first package structure PS1 and a second package structure PS2 connected to each other through the interposer substrate 700.

The first package structure PS1 may be a high-performance memory device such as high bandwidth memory (HBM) or hybrid memory cubic (HMC). For example, the first package structure PS1 may be a semiconductor package having the same or similar characteristics as those described with reference to FIGS. 5A to 6C. The first package structure PS1 may be connected to the interposer substrate 700 through metal bumps BP.

The second package structure PS2 may be a bare chip or a packaged chip on which a logic circuit or a memory circuit is formed. For example, the second package structure PS2 may be a stacked chip structure having the same or similar characteristics as those described with reference to FIGS. 7A and 7B. The second package structure PS2 may be connected to the interposer substrate 700 through metal bumps BP. The second package structure PS2 may include a different type of semiconductor chip from the first package structure PS1. For example, the first package structure PS1 may include a logic chip, and the second package structure PS2 may include a memory chip.

The package substrate 600 may be a support substrate on which the interposer substrate 700 is mounted, and may be a substrate for a semiconductor package, including a printed circuit board (PCB), a ceramic substrate, a glass substrate, a tape interconnection substrate, and the like. The package substrate 600 may include a lower pad 612, an upper pad 611, and an interconnection circuit 613. An external connection bump 620 connected to the lower pad 612 may be disposed on the lower surface of the package substrate 600. The external connection bump 620 may include, for example, a solder ball.

The interposer substrate 700 may include a substrate 701, a lower protective layer 703, a lower terminal 705, an interconnect structure 710, a conductive bump 720, and a through-via 730. The first package structure PS1 and the second package structure PS2 may be electrically connected to each other via the interposer substrate 700.

The substrate 701 may be formed of any one of, for example, silicon, organic, plastic, and glass substrates. For example, when the substrate 701 is a silicon substrate, the interposer substrate 700 may be referred to as a silicon interposer. Unlike what is illustrated in the drawing, when the substrate 701 is an organic substrate, the interposer substrate 700 may be referred to as a panel interposer.

The lower terminal 705 may be connected to the through-via 730. The lower terminal 705 may be electrically connected to the package substrate 600 through the conductive bumps 720.

The interconnect structure 710 is disposed on the upper surface of the substrate 701 and may include an interlayer insulating layer 711 and a single-layer or multilayer interconnection 712. When the interconnect structure 710 has a multilayer interconnect structure, interconnection patterns of different layers may be connected to each other through contact vias. An upper terminal 704 connected to the interconnect structure 712 may be disposed on the interconnect structure 710.

The through-via 730 may extend from the top to the bottom of the substrate 701 and penetrate the substrate 701. In an example, the through-via 730 extends into the interior of the interconnect structure 710, and may also be electrically connected to the interconnection 712. In the case in which the substrate 701 is silicon, the through-via 730 may be referred to as a TSV.

FIG. 9 is a cross-sectional view of a semiconductor package 10E according to one or more embodiments.

Referring to FIG. 9, a semiconductor package 10E of one or more embodiments may have the same or similar features as those described with reference to FIGS. 1 to 4C, except that both the first semiconductor chip 100 and the second semiconductor chip 200 include top conductors extending in respective shorter side directions D2.

The connection bumps 236 may include a pillar portion PL and a solder portion SD. The pillar portion PL includes copper (Cu) or an alloy of copper (Cu), and the solder portion SD may include a low melting point metal, such as tin (Sn) or an alloy containing tin (Sn) (for example, Sn—Ag, or Sn—Ag—Cu). For example, the connection bumps 236 may include only the pillar portion PL or only the solder portion (SD).

The semiconductor package 10E of one or more embodiments may include a first mold layer 261 and a second mold layer 262. The first mold layer 261 and the second mold layer 262 may be layers of an inorganic material such as silicon oxide (SiO), silicon nitride (SiN), or silicon carbonitride (SiCN), and may also be a polymer resin layer depending on one or more embodiments.

The first mold layer 261 may cover the first surface 210S1 and the side surface of the second substrate 210, and a portion (referring to a portion protruding onto the first surface 210S1) of the side surface of each of the second through-electrodes 240. The second upper pads PV22 and the second upper passivation layer PSV22 may be disposed on the first mold layer 261. The second mold layer 262 may cover the side and upper surfaces of the first semiconductor chip 100, on the second upper passivation layer PSV22.

As will be described later, the first semiconductor chip 100 and the second semiconductor chip 200 of this embodiment are bent and pre-bonded during the manufacturing process, and thus may include top conductors contacting the first lower pads PD1 and the second lower pads PD21, respectively, and extending in the shorter side direction D2.

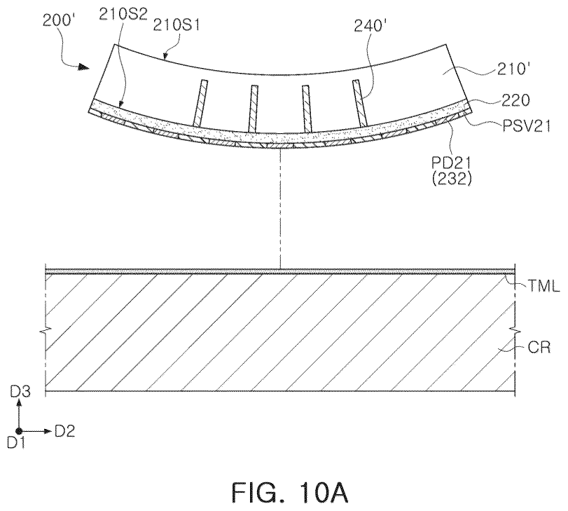

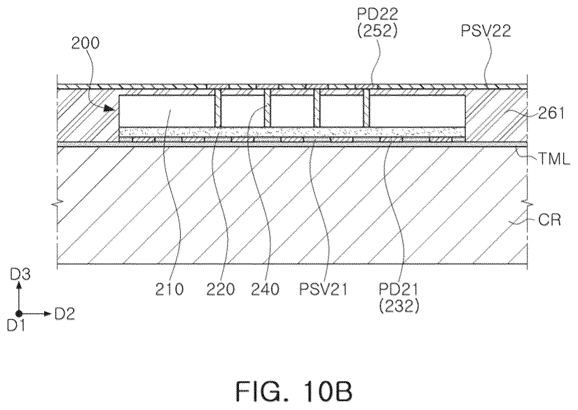

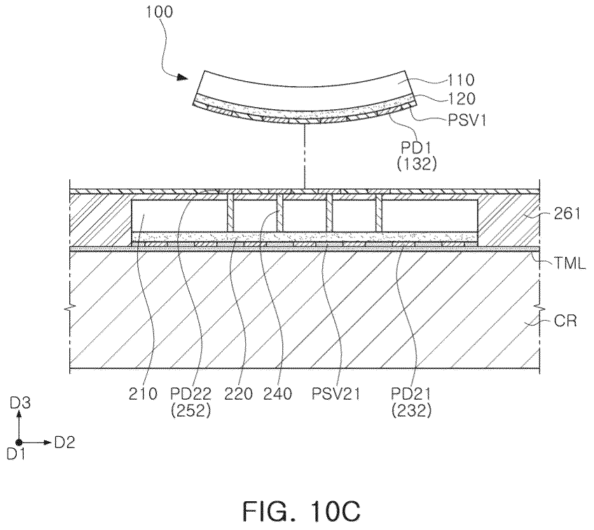

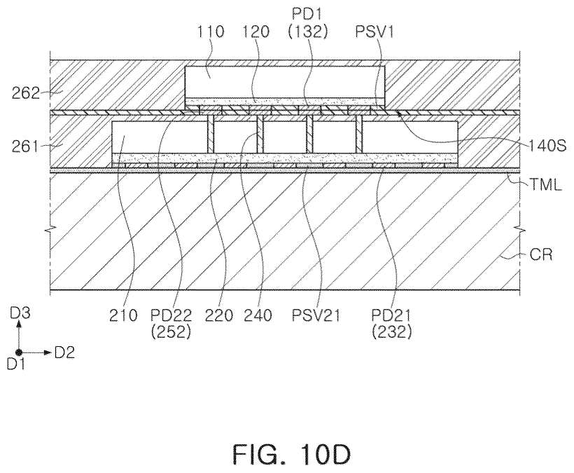

FIGS. 10A to 10D are diagrams illustrating a manufacturing process of the semiconductor package 10E illustrated in FIG. 9.

Referring to FIG. 10A, a second preliminary semiconductor chip 200′ may be disposed on a temporary bonding layer TML of a recombinant carrier CR.

To illustrate the manufacturing process of the semiconductor package 10E illustrated in FIG. 9, only one unit of the recombinant carrier CR is illustrated. For example, the recombinant carrier CR may be a 6-inch, 8-inch, 12-inch silicon wafer, or the like, containing dozens or more of the units illustrated in the drawing. Hereinafter, for convenience of explanation, the manufacturing process of the semiconductor package will be described focusing on one unit illustrated in the drawing. The temporary bonding layer TML may include silicon oxide (SiO). The temporary bonding layer TML may be formed using a PVD or CVD process.

The second preliminary semiconductor chip 200′ may be a known good die (KGD) for which testing has been completed. The second preliminary semiconductor chip 200′ may include a second preliminary substrate 210′, second preliminary through-electrodes 240′, a second circuit layer 220, second lower pads PD21, and a second lower passivation layer PSV21. The second preliminary substrate 210′ may be a silicon die whose thickness has not been adjusted through a back-grinding process. The second preliminary semiconductor chip 200′ may be disposed so that the second lower pads PD21 and the second lower passivation layer PSV21 are in contact with the temporary bonding layer TML. Thereafter, a thermal compression process may be performed to bond the second lower passivation layer PSV21 and the temporary bonding layer TML. Since the second preliminary semiconductor chip 200′ is attached in a bent state in the longer side direction D1 and the shorter side direction D2, voids generated at the interface with the temporary bonding layer TML may be reduced. Additionally, in the subsequent thermal compression process, moisture and voids may be more easily discharged in the shorter side direction D2 of the second preliminary semiconductor chip 200′.

Thereafter, a back grinding process and an etch-back process are applied to the second preliminary substrate 210′, so that the thickness of the second preliminary substrate 210′ is reduced, and the second preliminary through-electrodes 240′ may protrude to one surface of the second substrate 210.

Referring to FIG. 10B, a first mold layer 261, a second upper passivation layer PSV22, and second upper pads PD22 may be formed. The first mold layer 261 may be formed to completely cover the second semiconductor chip 200 and the second through-electrodes 240. Thereafter, a CMP process is applied to the first mold layer 261, so that the second through-electrodes 240 may be exposed to the upper surface of the first mold layer 261.

The second upper passivation layer PSV22 includes silicon oxide (SiO) and may be formed using a PVD or CVD process. The second upper pads PD22 may be formed in the second upper passivation layer PSV22 patterned using a photosensitive material layer and a photolithography process. The second upper pads PD22 include metal such as copper (Cu), titanium (Ti) or the like, and may be formed through a plating process. The second upper passivation layer PSV22 and the second upper pads PD22 may be planarized by a CMP process.

Referring to FIG. 10C, the first semiconductor chip 100 may be placed on the first mold layer 261. The first semiconductor chip 100 may be a tested KGD. The first semiconductor chip 100 may include a first substrate 110, a first circuit layer 120, a first passivation layer PSV1, and first lower pads PD1. The first semiconductor chip 100 may be placed so that the first lower pads PD1 are aligned with the second upper pads PD22. Thereafter, a thermal compression process may be performed to bond the first passivation layer PSV1 and the second upper passivation layer PSV22. Since the first semiconductor chip 100 is attached in a bent state in the longer side direction D1 and the shorter side direction D2, voids generated at the interface with the second upper passivation layer PSV22 may be reduced. Additionally, in the subsequent thermal compression process, moisture and voids may be more easily discharged in the shorter side direction D2 of the first semiconductor chip 100.

Referring to FIG. 10D, the second mold layer 262 may be formed. The second mold layer 262 may be formed to cover the upper surface of the first semiconductor chip 100. The second mold layer 262 may include, for example, silicon oxide (SiO) and may be formed using a PVD or CVD process. Afterwards, the recombinant carrier CR and the temporary bonding layer TML may be removed. The recombinant carrier CR and the temporary bonding layer TML may be removed using a combination of grinding and etching processes. For example, a portion of the temporary bonding layer TML may remain and serve as a protective layer covering the second lower pads PD21. Thereafter, the unit packages may be separated by forming connection bumps on the second lower pads PD21 and then performing a dicing process.

FIG. 11A is a cross-sectional view of a semiconductor package 10F according to one or more embodiments, and FIG. 11B is a partial enlarged view of region ‘C’ of FIG. 11A.

Referring to FIGS. 11A and 11B, the semiconductor package 10F of one or more embodiments may have the same or similar features as those described with reference to FIGS. 1A to 4C, except that the second circuit layer 220 is disposed on the first surface 210S1 of the second substrate 210. In this embodiment, the first surface 210S1 of the second substrate 210 may be referred to as the front surface, and the second surface 210S2 of the second substrate 210 may be referred to as the back surface.

The second circuit layer 220 may be disposed on the first surface 210S1 of the second substrate 210 on which the conductive region 112 is formed. The second circuit layer 220 may include individual elements ID, a second insulating layer IL2, and a second interconnection IC2. Hereinafter, the second insulating layer IL2 may be referred to as a front insulating layer or an interlayer insulating layer 221. The second interconnection IC2 may be referred to as the interconnect structure 225.

The second interconnection IC2 may include second intermediate conductors MC2 and second top conductors TC2. The second top conductors TC2 may be referred to as connection conductors. The second intermediate conductors MC2 may be disposed in the second insulating layer IL2. The second intermediate conductors MC2 may be positioned between the first surface 210S1 of the second substrate 210 and the second top conductors TC2. A thickness T2 of the second top conductors TC2 may be greater than a thickness t2 of the second intermediate conductors MC2. The thickness T2 of the second top conductors TC2 may be greater than or equal to about 1 μm, for example, range from about 1 μm to about 30 μm, from about 1 μm to about 20 μm, from about 1 μm to about 10 μm, from about 1 μm to about 5 μm, or the like, but embodiments are not limited thereto. The second top conductors TC2 may include aluminum (Al) or an alloy thereof, but embodiments are not limited thereto.

In one or more embodiments, the second top conductors TC2 may extend lengthwise in the longer side direction (D1 direction) of the second semiconductor chip 200. For example, when the second semiconductor chip 200 is a base wafer or a base chip, the second top conductors TC2 may be formed in a long rectangular shape in the longer side direction D1 of the second semiconductor chip 200. On a plane, the second top conductors TC2 may intersect the first top conductors TC1, but embodiments are not limited thereto. According to the design of the second semiconductor chip 200, the second top conductors TC2 may be formed in a long rectangular shape in the shorter side direction D2 of the second semiconductor chip 200.

As set forth above, according to example embodiments, as the top conductors of a semiconductor chip attached to a base chip extend in the direction of the shorter side of the semiconductor chip, a semiconductor package having improved bonding surface quality and reliability may be provided.

While example embodiments have been illustrated and described above, it will be apparent to those skilled in the art that modifications and variations could be made without departing from the scope of the present inventive concept as defined by the appended claims and their equivalents.

The invention claimed is:

1. A semiconductor package comprising:
a first semiconductor chip comprising a substrate, interconnects on a first surface of the substrate, an insulating layer on at least a portion of the interconnects, first lower pads on the interconnects, and a first passivation layer on at least a portion of each of the first lower pads; and
a second semiconductor chip comprising second upper pads in contact with the first lower pads, a second passivation layer on at least a portion of each of the second upper pads and in contact with the first passivation layer, second lower pads opposite to the second upper pads, and through-electrodes electrically connecting the second upper pads and the second lower pads,
wherein in a plan view, the first semiconductor chip has a first longer side extending in a first direction and a first shorter side extending in a second direction, intersecting the first direction,
wherein the interconnects comprise intermediate conductors and connection conductors between the intermediate conductors and the first lower pads, a thickness of each of the connection conductors being greater than a thickness of each of the intermediate conductors, and
wherein the connection conductors are disposed in the first direction and the second direction, and a number of the connection conductors in the first direction is greater than a number of the connection conductors in the second direction.

2. The semiconductor package of claim 1, wherein each of the connection conductors have first sides extending in the first direction and second sides extending in the second direction, and
wherein a length of each of the first sides is shorter than a length of each of the second sides.

3. The semiconductor package of claim 2, wherein a first ratio of a sum of lengths of the first sides adjacent to the first longer side and a length of the first longer side is lower than a second ratio of a sum of lengths of the second sides adjacent to the first shorter side and a length of the first shorter side.

4. The semiconductor package of claim 2, wherein the length of the first sides ranges from 1 μm to 50 μm.

5. The semiconductor package of claim 1, wherein a number of first spaces between the connection conductors in the first direction is greater than a number of second spaces between the connection conductors in the second direction.

6. (canceled)

7. The semiconductor package of claim 5, wherein the first spaces do not overlap the connection conductors in the second direction.

8. The semiconductor package of claim 1, wherein the thickness of the connection conductors is greater than or equal to 1 μm.

9. The semiconductor package of claim 1, wherein the connection conductors comprise a first group of connection conductors connected to two or more of the first lower pads disposed in the second direction.

10. The semiconductor package of claim 1, wherein the connection conductors comprise a second group of connection conductors connected 1:1 to the first lower pads.

11. The semiconductor package of claim 1, wherein the connection conductors comprise a third group of connection conductors spaced apart from the first lower pads.

12. (canceled)

13. (canceled)

14. The semiconductor package of claim 1, wherein the first semiconductor chip comprises a plurality of first semiconductor chips stacked in a vertical direction on the second semiconductor chip, and
wherein at least some of the plurality of first semiconductor chips are on the second surface of the substrate, and comprise first upper pads in contact with the first lower pads adjacent to each other in the vertical direction, an upper passivation layer on at least a portion of each of the first upper pads and in contact with the first passivation layer adjacent thereto in the vertical direction, and through-electrodes penetrating through the substrate and electrically connecting the first upper pads to the first lower pads.

15. A semiconductor package comprising:
a first semiconductor chip comprising interconnects, first lower pads on the interconnects, and a first passivation layer on at least a portion of each of the first lower pads; and
a second semiconductor chip comprising second upper pads in contact with the first lower pads, a second passivation layer on at least a portion of each of the second upper pads and in contact with the first passivation layer, second lower pads opposite to the second upper pads, and through-electrodes electrically connecting the second upper pads and the second lower pads,
wherein the interconnects comprise intermediate conductors and top conductors between the intermediate conductors and the first lower pads,
wherein, in a plan view, the first semiconductor chip has a first longer side extending in a first direction and a first shorter side extending in a second direction, intersecting the first direction, and
wherein, in the plan view, the top conductors has first sides having a first length in the first direction, and second sides having a second length longer than the first length in the second direction.

16. The semiconductor package of claim 15, wherein the first lengths of the first sides are equal to each other.

17. The semiconductor package of claim 15, wherein the top conductors comprise a first group of top conductors and a second group of top conductors, and
wherein lengths of the second sides of the first group of top conductors are different from lengths of the second sides of the second group of top conductors.

18. The semiconductor package of claim 17, wherein the lengths of the second sides of the first group of the top conductors is greater than the lengths of the second sides of the second group of the top conductors.

19. The semiconductor package of claim 18, wherein the intermediate conductors comprise a signal interconnection, a power interconnection, and a ground interconnection,
wherein the first group of the top conductors are connected to at least one of the power interconnection and the ground interconnection, and
wherein the second group of the top conductors are connected to the signal interconnection.

20. A semiconductor package comprising:
a first semiconductor chip comprising interconnects, first lower pads on the interconnects, and a first passivation layer on at least a portion of each of the first lower pads;
a second semiconductor chip comprising second upper pads in contact with the first lower pads, and a second passivation layer on at least a portion of each of the second upper pads and in contact with the first passivation layer; and
a mold layer on the second semiconductor chip and adjacent to at least a side surface of the first semiconductor chip,
wherein, in a plan view, the first semiconductor chip has a first longer side extending in a first direction and a first shorter side extending in a second direction, intersecting the first direction,
wherein, in the plan view, the second semiconductor chip has a second longer side that is longer than the first longer side in the first direction, and a second shorter side that is longer than the first shorter side in the second direction,
wherein the interconnects comprise intermediate conductors and top conductors connecting the intermediate conductors and the first lower pads, and
wherein each of the top conductors has a rectangular shape elongated in the second direction.

21. The semiconductor package of claim 20, wherein, in the plan view, the first semiconductor chip comprises a first circuit region extending in the first direction, and a second circuit region adjacent to at least one side of the first circuit region in the second direction, and
wherein the top conductors comprise a first group of top conductors in the first circuit region and a second group of top conductors in the second circuit region.

22. The semiconductor package of claim 21, wherein a length of each of the first group of the top conductors in the second direction is greater than a length of each of the second group of the top conductors in the second direction.

23. The semiconductor package of claim 21, wherein the first circuit region comprises a memory circuit, and
wherein the second circuit region includes an input/output circuit for the memory circuit.

24. (canceled)

25. (canceled)
